(19) United States
(12) Patent Application Publication
(10) Pub. No.: US 2014/0134844 A1
(43) Pub. Date: May 15, 2014

(54) METHOD FOR PROCESSING A DIE

(71) Applicant: INFINEON TECHNOLOGIES DRESDEN GMBH, Dresden (DE)

(72) Inventors: Stefan Tegen, Dresden (DE); Marko Lemke, Dresden (DE)

(73) Assignee: INFINEON TECHNOLOGIES DRESDEN GMBH, Dresden (DE)

(21) Appl. No.: 13/674,136

(22) Filed: Nov. 12, 2012

(51) Int. Cl. H01L 21/308

(52) U.S. Cl. CPC H01L 21/308
USPC 438/702

(57) ABSTRACT

In various embodiments, a method for processing a die is provided. The method may include forming a periodic structure at least one of over and in a carrier, the periodic structure including a plurality of structure elements; depositing masking material over the periodic structure; partially removing masking material to expose at least one structure element but not all of the structure elements; and removing the exposed at least one structure element.

### TECHNICAL FIELD

Various embodiments relate to a method for processing a die, a method for processing a wafer, and a method for manufacturing a chip.

### BACKGROUND

Generally, fabricating integrated circuits, dies or chips give the need of processing an aspired arrangement of structure elements. Using standard lithographic processes and subsequently etching processes there are usually problems in processing arrays of symmetrically arranged structures, since the edges of symmetrically arranged structures may not be processed in a sufficiently high quality due to so-called micro loading. Micro loading refers to an effect due to which structure elements situated at edges of a symmetric arrangement are subjected to different conditions during an etching process than structure elements within the symmetric arrangement.

There are various attempts to reduce this effect including for instance dummy structures, or additional process steps during fabrication. However, in doing so, other effects may arise. By way of example, dummy structures may be space consuming, additional process steps may be related to higher costs, a low reproducibility of additional process steps especially for small structure elements due to overlay errors may occur.

If the used structure elements are small, e.g. FinFETs (a FinFET is a fin-based, multigate field effect transistor), damages as well as changes in shape or size of a structure element due to micro loading may cause distinct affects which may result in suppressing the functionality of these small structure elements. These situations may occur in transition sections between dense structures, e.g. line arrays, and isotropic structures, e.g. peripheral structures. Further, the mentioned effects may be worsened, if not only the structure elements are small, but also the size of the arrays is reduced, since the ratio between the total amount of structures and structures situated at edges, which are therefore affected by inhomogeneity of shape or size due to microloading, would increase.

### SUMMARY

In various embodiments, a method for processing a die is provided. The method may include forming a periodic structure at least one of over and in a carrier, the periodic structure including a plurality of structure elements; depositing masking material over the periodic structure; partially removing masking material to expose at least one structure element but not all of the structure elements; and removing the exposed at least one structure element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a method for processing a die in a flow diagram in accordance with various embodiments.

FIG. 2A schematically shows a cross section of a carrier at an initial processing stage in accordance with various embodiments.

FIG. 2B schematically shows a cross section of the carrier at a first processing stage, wherein a periodic structure is formed over the carrier in accordance with various embodiments.

FIG. 2C schematically shows a cross section of a carrier at a second processing stage, wherein a masking material is deposited covering the periodic structure formed over the carrier in accordance with various embodiments.

FIG. 2D schematically shows a cross section of a carrier at a third processing stage, wherein part of the masking material is removed exposing at least one structure element but not all of the structure elements in accordance with various embodiments.

FIG. 2E schematically shows a cross section of a carrier at a fourth processing stage, wherein the exposed at least one structure element is removed in accordance with various embodiments.

FIG. 2F schematically shows a cross section of a carrier at a further processing stage, wherein a recess is formed in the carrier using the remaining masking material as a removal mask in accordance with various embodiments.

FIG. 2G schematically shows a cross section of a carrier at a further processing stage, wherein the remaining masking material is removed exposing all structure elements after the recess is formed in accordance with various embodiments.

FIG. 2H schematically shows a cross section of a carrier at a further processing stage, wherein a material is formed into a region between the remaining masking material where the at least one structure element has been removed in accordance with various embodiments.

FIG. 3A schematically shows a cross section of a carrier at an initial processing stage in accordance with various embodiments.

FIG. 3B schematically shows a cross section of the carrier at a first processing stage, wherein a periodic structure is formed in the carrier in accordance with various embodiments.

FIG. 4A schematically shows a cross section of a carrier at a third processing stage, wherein part of the masking material is removed exposing one structure element in accordance with various embodiments.

FIG. 4B schematically shows a cross section of a carrier at a fourth processing stage, wherein the exposed exactly one structure element is removed in accordance with various embodiments.

FIG. 4C schematically shows a cross section of a carrier at a further processing stage, wherein a recess is formed in the carrier using the remaining masking material as a removal mask in accordance with various embodiments.

FIG. 4D schematically shows a cross section of a carrier at a further processing stage, wherein the remaining masking material is removed exposing all structure elements after the recess is formed in accordance with various embodiments.

FIG. 4E schematically shows a cross section of a carrier at a further processing stage, wherein a material is formed into a region between the remaining masking material where the exactly one structure element has been removed in accordance with various embodiments.

FIG. 5A and FIG. 5B schematically show a cross section of a carrier during an extended third processing stage, respectively, wherein part of the masking material is removed exposing at least one structure element including a first removal structure and second removal structure in accordance with various embodiments.

FIG. 5C and FIG. 5D schematically show a cross section of a carrier during an extended third processing stage, respectively, wherein part of the masking material is removed exposing exactly one structure element including a first removal structure and second removal structure in accordance with various embodiments.

FIG. 6 shows a method for processing a wafer including a plurality of dies in a flow diagram in accordance with various embodiments.

FIG. 7 shows a method for manufacturing a chip in a flow diagram in accordance with various embodiments.

FIG. 8 shows schematically shows a top view of a carrier including a plurality of periodically aligned structure elements in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material. The word “remove” used with regards to “remove” a structure element may be used herein to mean that, if the structure elements including holes, the structure element is changed in the shape and size.

In various embodiments, an optimized process for fabricating an array of symmetrically aligned structure elements is provided.

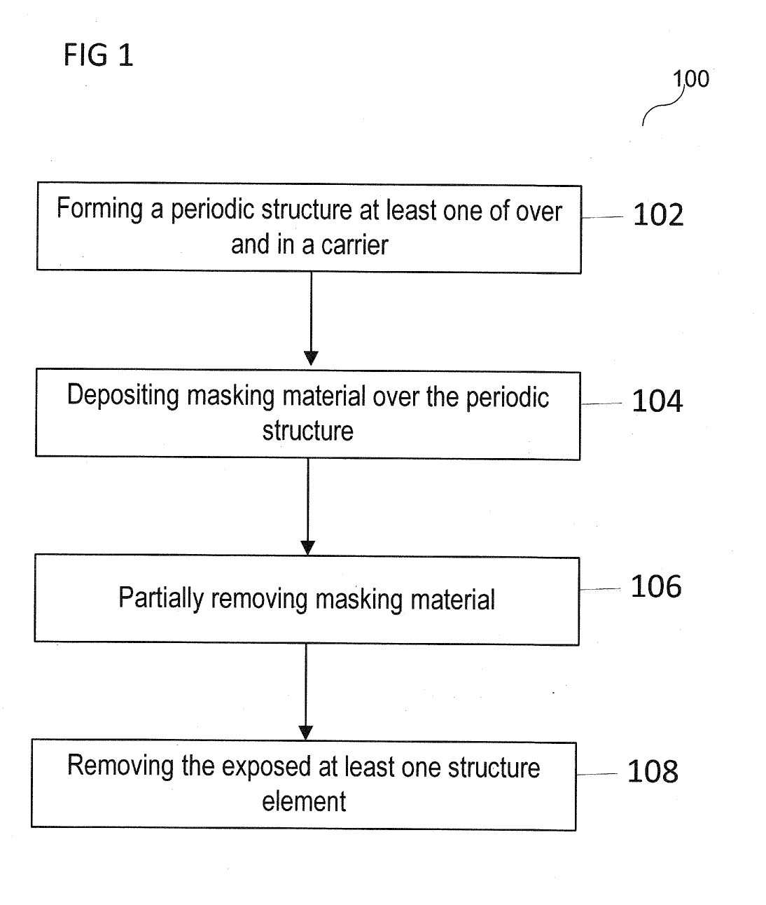

FIG. 1 shows a method 100 for processing a die in accordance with various embodiments in a flow diagram. The method 100 may include, in a first process 102, forming a periodic structure at least one of over and in a carrier. Thus, an initial structure may be formed. The periodic structure may include a plurality of structure elements. The method may further include, in a second process 104, depositing masking material over the periodic structure, in a third process 106, partially removing masking material exposing at least one structure element but not all of the structure elements, and, in a fourth process 108, removing the exposed at least one structure element. According to various embodiments, the remaining masking material may be used for further processes, e.g. forming at least one isolating trench or forming at least one electrical contact. As a result, arrays may be formed having structure elements being equal in shape and size and therefore having uniform electrical properties, even at the edges of the formed array.

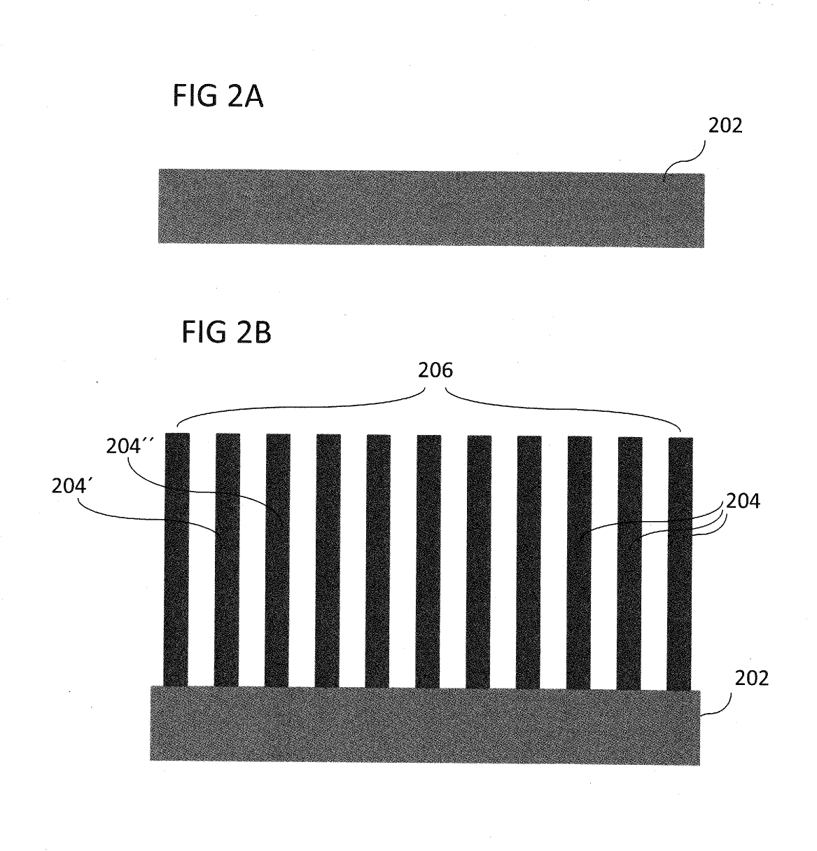

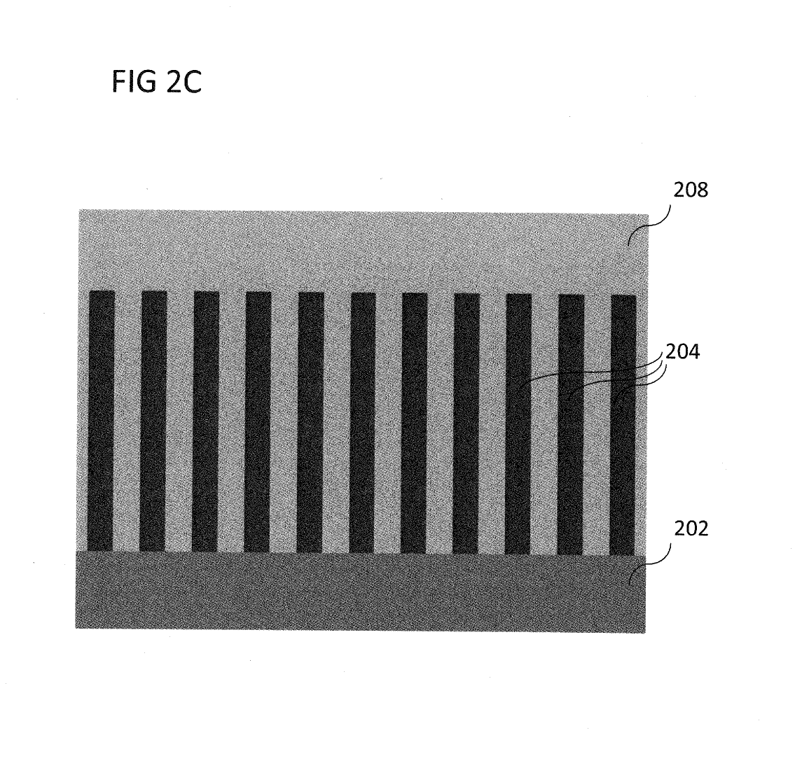

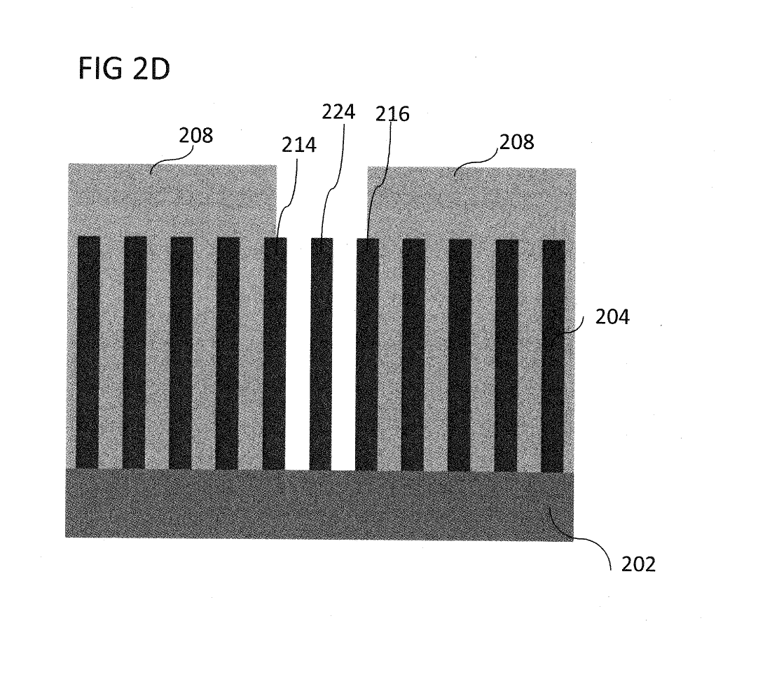

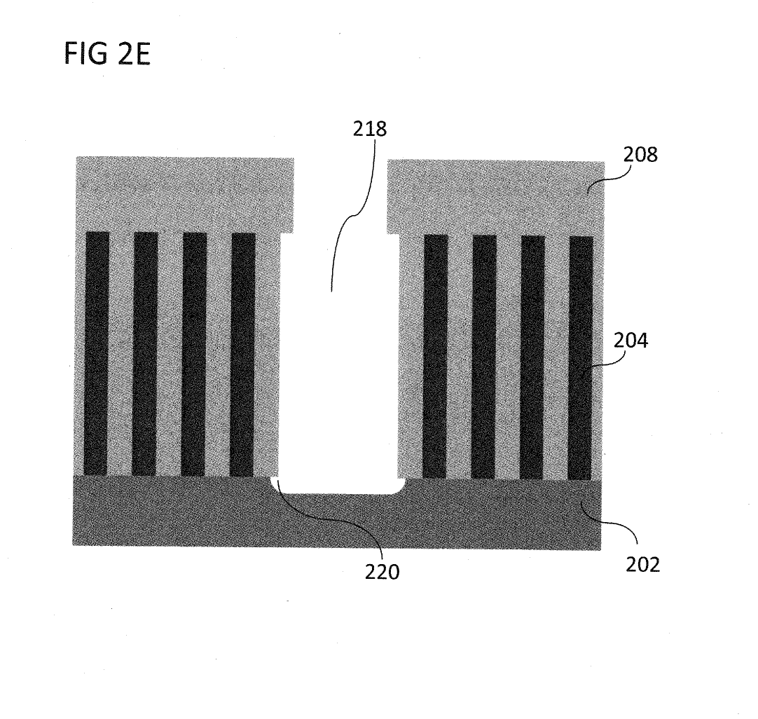

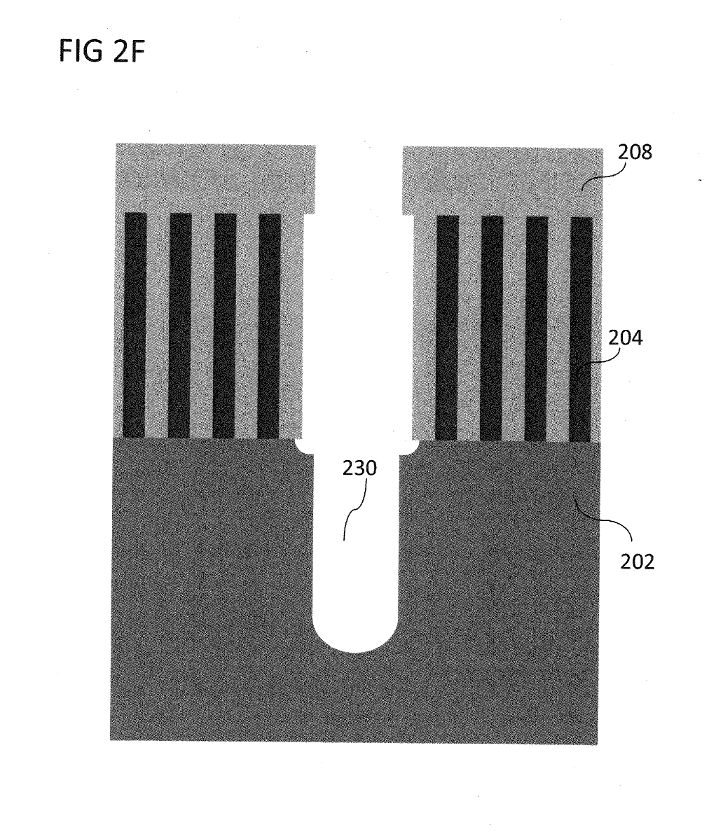

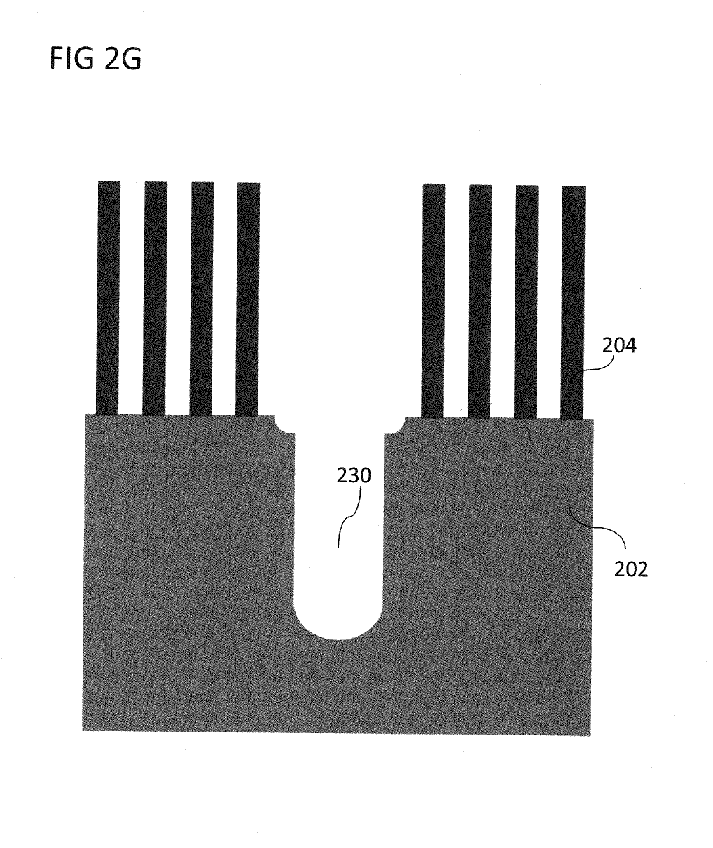

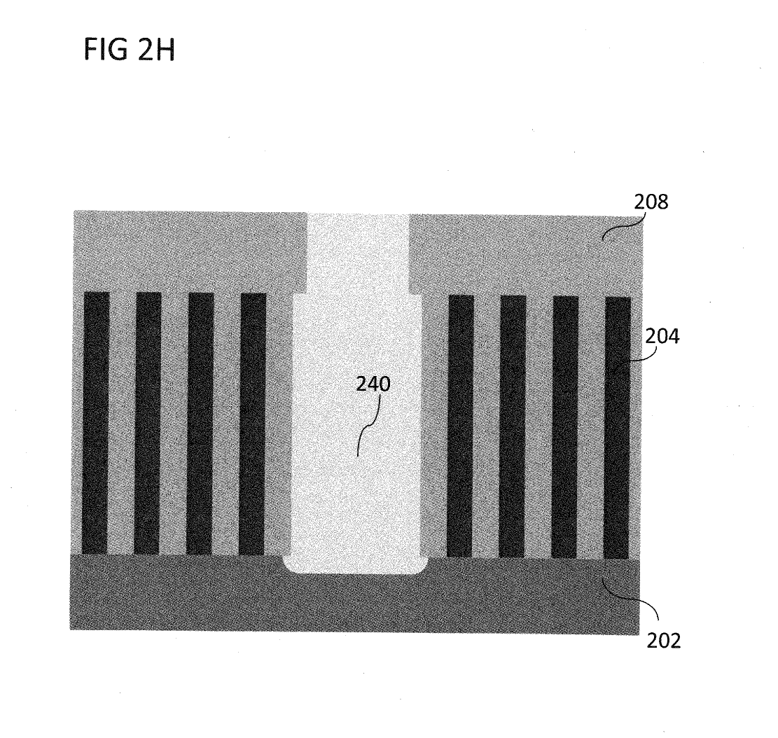

FIG. 2A schematically shows a cross section of a carrier 202 at an initial processing stage in accordance with various embodiments. According to various embodiments, the carrier (e.g. substrate or a wafer substrate) may be made of semiconductor materials of various types, including silicon, germanium, Group III to V or other types, including polymers, for example, although in another embodiment of the invention, also other suitable materials can be used. In an embodiment, the substrate is made of silicon (doped or undoped), in an alternative embodiment, the substrate is silicon on insulator (SOI) wafer. As an alternative, any other suitable semiconductor materials can be used for the substrate, for example semiconductor compound material such as gallium arsenide (GaAs), indium phosphide (InP), but also any suitable ternary semiconductor compound material or quaternary semiconductor compound material such as indium gallium arsenide (InGaAs). Although carrier 202 is shown schematically as a single layer in FIG. 2A, it may be understood that, in some embodiments, at least part of carrier 202 may include one or more sublayers, structures and/or elements.

As described above with reference to method 100, a periodic structure may be formed at least one of over and in a carrier in a first process 102 according to various embodiments. The periodic structure may include a plurality of structure elements. FIG. 2B schematically shows a cross section of a carrier 202 at a first processing stage, wherein a periodic structure 206 is formed over the carrier 202 including a plurality of structure elements 204 in accordance with various embodiments. Forming the periodic structure 206 may include an application of common processes, such as deposition processes, lithographic processes and/or etching processes, for example. A structure element 204 may have the shape of a fin, a cuboid, or a ball or any other suitable shape, if desired. According to various embodiments, the plurality of structure elements may include structure elements 204 all having the same shape or structure elements 204 having different shapes. According to various embodiments, the structure elements 204 may be formed of at least one material from the following group of materials: poly crystalline silicon, single crystalline silicon, a metal, an insulator or other materials used in semiconductor fabrication, such as gallium arsenide, silicon germanium, silicon carbide, silicon nitride, indium phosphide or metals, since the described method 100 is not limited to a specific material or combination of materials in general. Further, the structure elements 204 may be formed of the same material as the carrier 202 according to an embodiment.

In various embodiments, the periodic structure 206 may be formed with a distance between two adjacent structure elements, e.g. a first structure element 204′ and a second structure element 204″ (which is immediately adjacent to the first structure element 204′), in the range from about 10 nm to about 10 μm. Moreover, the plurality of structure elements 204 may also include a plurality of holes (e.g. trenches) formed into the carrier 202. More precisely, in applying method 100 there is neither a general restriction regarding to the shape of the structure elements, nor a general constraint in the method which may be utilized for fabricating the periodic structure. In various embodiments, the structure elements of the periodic structure 206 may have a height (e.g. a fin height) in the range from about 10 nm to about 10 μm.

In various embodiments, the plurality of structure elements 204 may be formed by depositing a layer on or above the (e.g. entire surface of) carrier 202, wherein the structure elements 204 will be formed by the layer after having structured the same. After the layer has been deposited, one or more masks may be formed including one or more hard masks (e.g. made of silicon oxide or silicon nitride) and/or one or more (photosensitive) resist structures which are patterned using one or more lithographic masks. After having patterned the one or more masks, a removal process (e.g. an etch process such as e.g. a wet etch or a dry etch process) may be carried out to remove material of the layer to thereby form the periodic structure 206.

As also described above with reference to method 100, a second process 104 may include depositing masking material over the periodic structure. FIG. 2C schematically shows a cross section of the carrier 202 at a second processing stage, wherein masking material 208 is deposited over the periodic structure 206 including the structure elements 204 in accordance with various embodiments. The masking material 208 may be deposited using a common process based on a chemical vapor deposition process (CVD-process), e.g. low pressure CVD or ultrahigh vacuum CVD, or based on a physical vapor deposition process (PVD-process), e.g. sputtering, or based on a spin-coating process. Using the deposition process, for example, sufficient edge coverage may be achieved so that the masking material 208 is covering the structure elements 204 completely (i.e. both sidewalls as well as the top surface of the structure elements 204). However, there may be the case that the masking material 208 does not completely cover the structure elements 204 in various embodiments. In this case, it may be provided that the masking material 208 at least completely separates, i.e. physically isolates, the structure elements 204 from each other, otherwise problems may occur regarding the exposure of the at least one structure element 204 in the following processes. The masking material 208 may include a hard mask material, e.g. at least one of the following materials: an oxide, a nitride, or carbon. Among these materials silicon oxide, silicon nitride, silicon oxy-nitride (SiOₓN_{y}), or titanium nitride may be used as an example. Furthermore, an organic material may also be used as a masking material, wherein the organic material may include a (e.g. photosensitive) resist material, e.g. photoresists, including one or more positive photoresists and/or one or more negative photoresists.

As also described above with reference to method 100, a third process 106 may include partially removing masking material exposing at least one structure element 204 but not all of the structure elements 204. According to various embodiments, partially removing masking material may at first include an additional process defining areas, where the masking material 208 may subsequently be removed. The additional process may be a common patterning process using an additional masking material, e.g. depositing an additional hard mask material (e.g. titanium nitride or silicon nitride) over the masking material 208, and an additional lithographic process, e.g. using a photoresist, and an additional etch process, e.g. an anisotropic etch process as for example dry etching, to open the hard mask defining the pattern for partially subsequently removing the masking material 208. FIG. 2D schematically shows a cross section of a carrier 202 at a third processing stage, wherein part of the masking material 208 is removed exposing at least one structure element but not all of the structure elements 214, 216, 224 in accordance with various embodiments. As illustrated in FIG. 2D, removing part of the masking material may completely expose a third structure element 224 and may partially expose a fourth structure element 214 and a fifth structure element 216. In the case that a structure element 214, 216 is partially exposed, it may be provided to expose at least one side or surface thereof completely, otherwise there may occur problems during removing the structure element during the following processes.

As also described above with reference to method 100, a fourth process 108 may include removing the exposed at least one structure element. FIG. 2E schematically shows a cross section of a carrier at a fourth processing stage, wherein the exposed at least one structure element (214, 216, 224 cf. FIG. 2D) is removed in accordance with various embodiments, thereby forming a hollow space 218. In various embodiments, the exposed at least one structure element 214, 216, 224 may be removed by means of an etch process. The etch process to remove the exposed at least one structure element may be realized using a wet etch process or a dry etch process. According to various embodiments, removing the exposed at least one structure element may include an isotropic etch process.

If an etch process also affecting the material of the carrier 202 may be performed, part of the carrier 202 may be removed as well (thereby forming a removed carrier portion 220, for example), as it is illustrated in FIG. 2E.

After having removed the at least one structure element, according to various embodiments, a recess 230 in the carrier 202 may be formed using the remaining masking material 208 as a removal mask, as it is shown in FIG. 2F. The structural width of the removal mask is correlated with the distance between two adjacent structure elements 204 and also with the outline dimension of a structure element 204, which is therefore correlated with the width of the recess 230, which can be formed. Forming the recess 230 into the carrier 202 may include an etch process using the remaining masking material 208 as an etch mask. By way of example, forming the recess 230 in the carrier 202 using an etch process may further include a dry etch process as well as a wet etch process. In various embodiments, if the shape of the recess 230 should be anisotropic (cf. FIG. 2F), e.g. to form an isolating trench, the etch process to form the recess 230 in the carrier 202 may include an anisotropic etch process.

According to various embodiments, after removing the exposed at least one structure element 214, 216, 224, the remaining masking material 208 can likewise be removed to expose other structure elements 204 including the exposure of all structure elements 204.

In various embodiments, masking material 208 may be removed after having removed the exposed at least one structure element 214, 216, 224, but before forming the recess 230. Furthermore, according to various embodiments, after the recess 230 in the carrier 202 has been formed, the remaining masking material 208 may likewise be removed to expose other structure elements, as exemplarily shown in FIG. 2G.

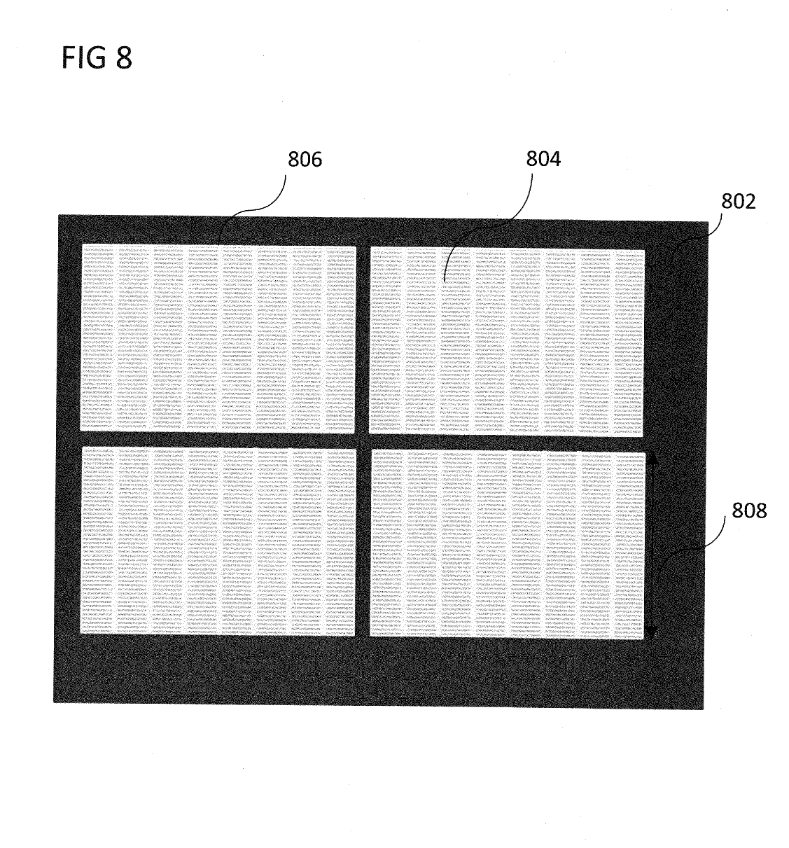

According to various embodiments, method 100, as described in FIG. 1 and FIG. 2A to FIG. 2G, may be used to form separated arrays having periodically aligned structure elements 204, e.g. FinFETs, being equal in shape and size and therefore having uniform electrical properties, since the remaining masking material 208 may be used as removal mask forming structures including for example isolating trenches within the initial periodic structure 206. Thus, self-assembled structures may be created using the methods 100, 600, 700 in accordance with various embodiments. As exemplarily shown in FIG. 8, separated arrays 806 having periodically aligned structure elements 804 may be formed over or in a carrier 802. The width 808 of the separated arrays 806, e.g. arrays 806 having periodically aligned structure elements 804, as for example FinFETs, may be varied as an integer multiple of the distance between two adjacent structure elements. According to various embodiments, the structure elements 804 forming self-assembled separated arrays 806 and moreover, structure elements 804 may be formed being equal in shape and size and therefore having uniform electrical properties, even at the edges of the formed array 806.

Furthermore, according to various embodiments, the recess 230 or isolating trench may be self-aligned within the initial periodic structure, if the removal mask is created by removing at least one structure element 204 and as a result the susceptibility of the describe method 100 to overlay errors is reduced, which increases the yield during a fabrication process. The alignment of separated arrays can be realized without using dummy structures and therefore without the need of additional space on the carrier 202. Moreover, the depth of the recess 230, which can be created in the carrier 202, e.g. to create an isolating trench 230, may be varied independently from other process parameters, e.g. the outline dimension of the structure elements. Besides this, the recess 230 or isolating trench 230 may be realized without the formation of raisings or steps, which occur in other common processes.

According to various embodiments, after having removed the at least one structure element 204, a material 240 may be formed into the region between the remaining masking material, where the at least one structure element has been removed, as shown exemplarily in FIG. 2H. The material 240 may be formed using a common process based on chemical vapor deposition (CVD) process, e.g. Low Pressure CVD or ultrahigh vacuum CVD or based on physical vapor deposition (PVD) process, e.g. sputtering, or based on an atomic layer deposition (ALD) process. The material 240 formed into a region between the remaining masking material 208 may serve for instance as an electrical contact. Therefore, the deposited material may include an electrically conductive material, such as poly-silicon. Furthermore, one or more metallically conductive materials may be used. The metallically conductive material(s) may include at least one of a metal from a group consisting of: tungsten, titanium, gold, silver, tantalum, or palladium. Additionally, after the deposition of material 240 the surface may be planarised using a common process, such as e.g. a chemical mechanical polishing (CMP) process.

According to an embodiment, forming a periodic structure at least one of over and in a carrier may also include forming a periodic structure over and in the carrier. Besides this, the periodically arranged structure elements may include different types of structure elements as for example fins and cuboids. In this regard, the periodic structure as described herein may be generated by the combination of individual structures having a certain periodicity.

Although the embodiments are described in a simplified two dimensional view, showing cross section at various processing stages, to illustrate the basic principles of the present invention, the method should be understood as a three dimensional process. By removing symmetric structure elements along a line, a line structure, e.g. an isolating trench or an electrical line-contact can be formed, whereas removing one symmetric structure element may lead to the formation of a dot like structure, e.g. a hole or an electrical point contact, according to the shape of the removed structure element.

According to various embodiments, modifications of the describe method 100, as shown in FIG. 1 and exemplified in FIG. 2A to FIG. 2H, are shown in following description.

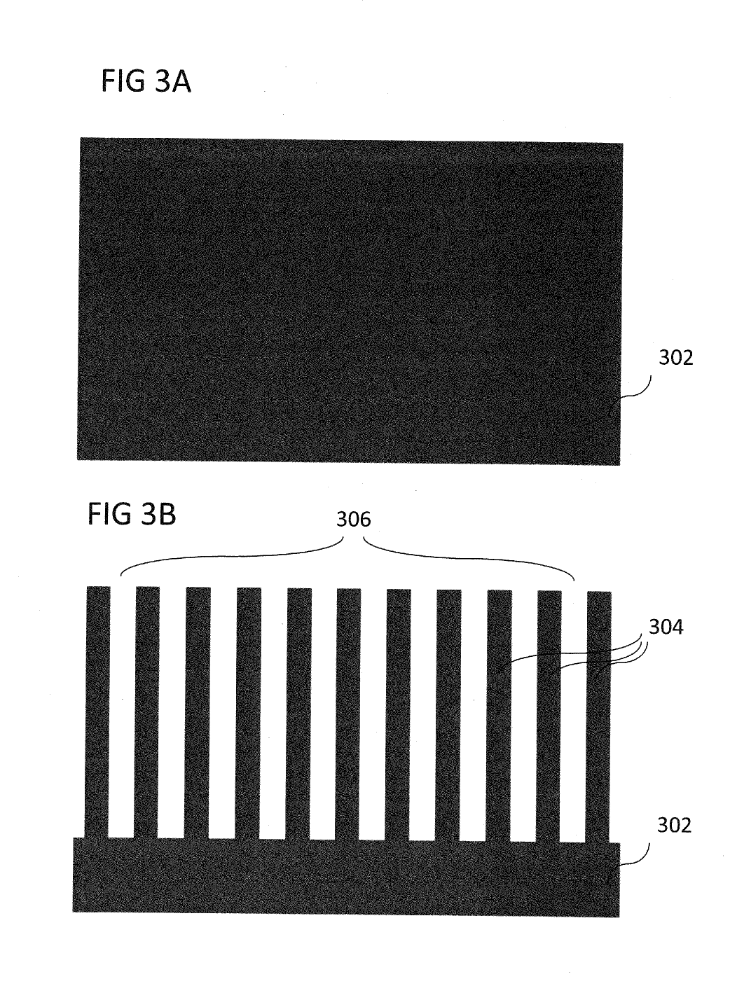

As shown in FIG. 3A and FIG. 3B, the periodic structure may be formed in the carrier 302, according to various embodiments. FIG. 3A schematically shows a cross section of a carrier 302 at an initial processing stage in accordance with various embodiments. Further, FIG. 3B schematically shows a cross section of the carrier 302 at a first processing stage, wherein a periodic structure 306 is formed in the carrier 302 in accordance with various embodiments. In other words, the periodic structure 306 may be formed from the same bulk material as the carrier 302. As illustrated in FIG. 3B, a plurality of structure elements 304 may be created in the carrier 302 forming the periodic structure 306.

In this regard, the periodic structure 306 may be formed by removing material from the carrier 302 and thus the structure elements 304 are created in the carrier 302. Removing the material from the carrier 302 may include common processes, such as lithographic processes and etching processes. The further processes referring to method 100 as already described and as will be described in the following, may be applied as well to the periodic structure 306 in the carrier 302 without any constraint.

In various embodiments, the plurality of structure elements 304 may be formed by removing material from the carrier 302 using one or more masks may be formed including one or more hard masks (e.g. made of silicon oxide or silicon nitride) and/or one or more (photosensitive) resist structures which are patterned using one or more lithographic masks. After having patterned the one or more masks, a removal process (e.g. an etch process such as e.g. a wet etch or a dry etch process) may be carried out to remove material of the layer to thereby form the periodic structure 306.

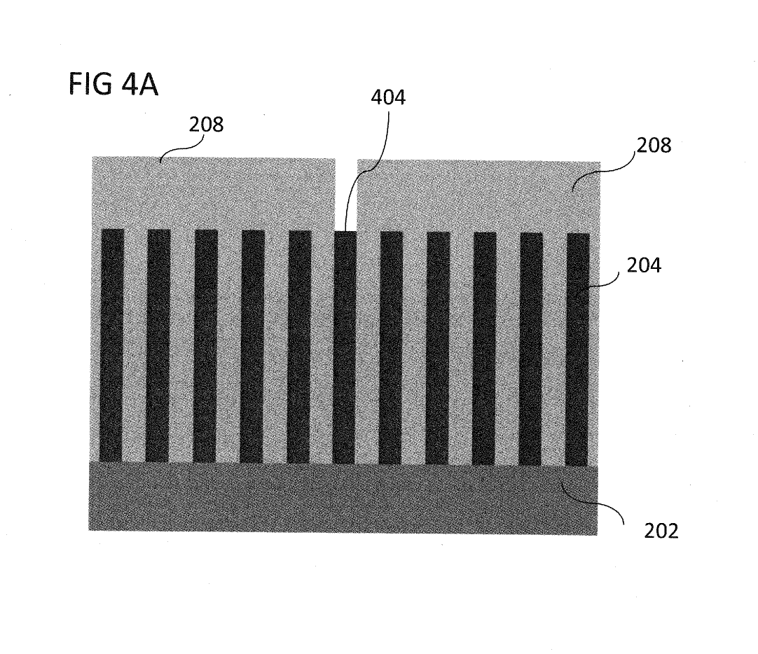

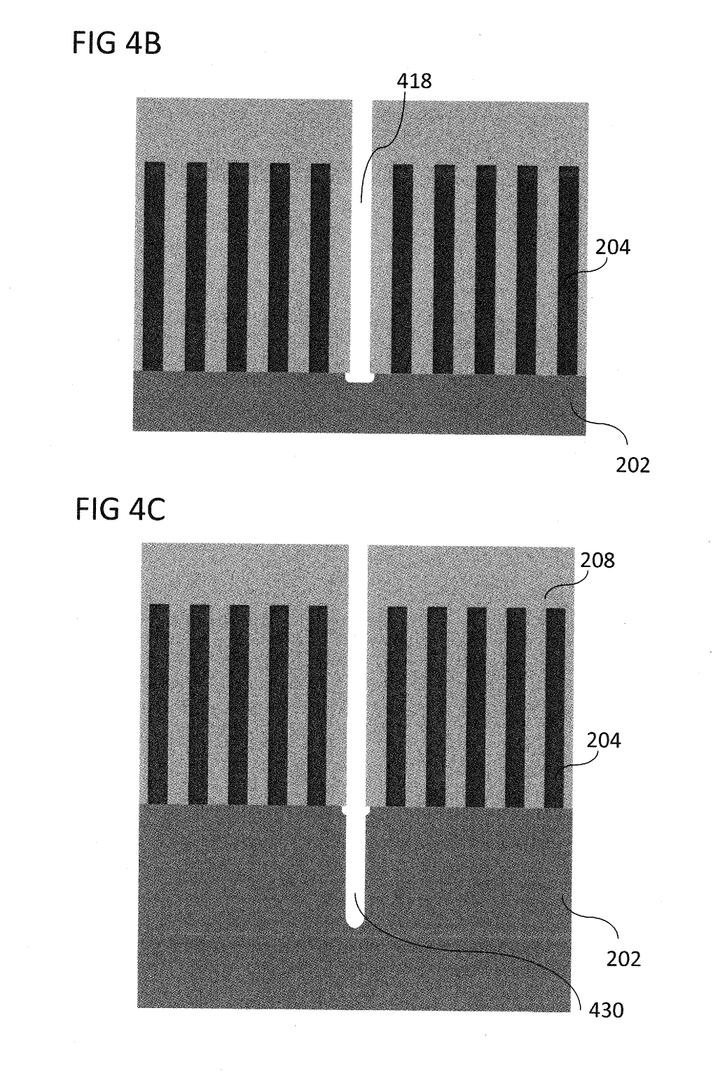

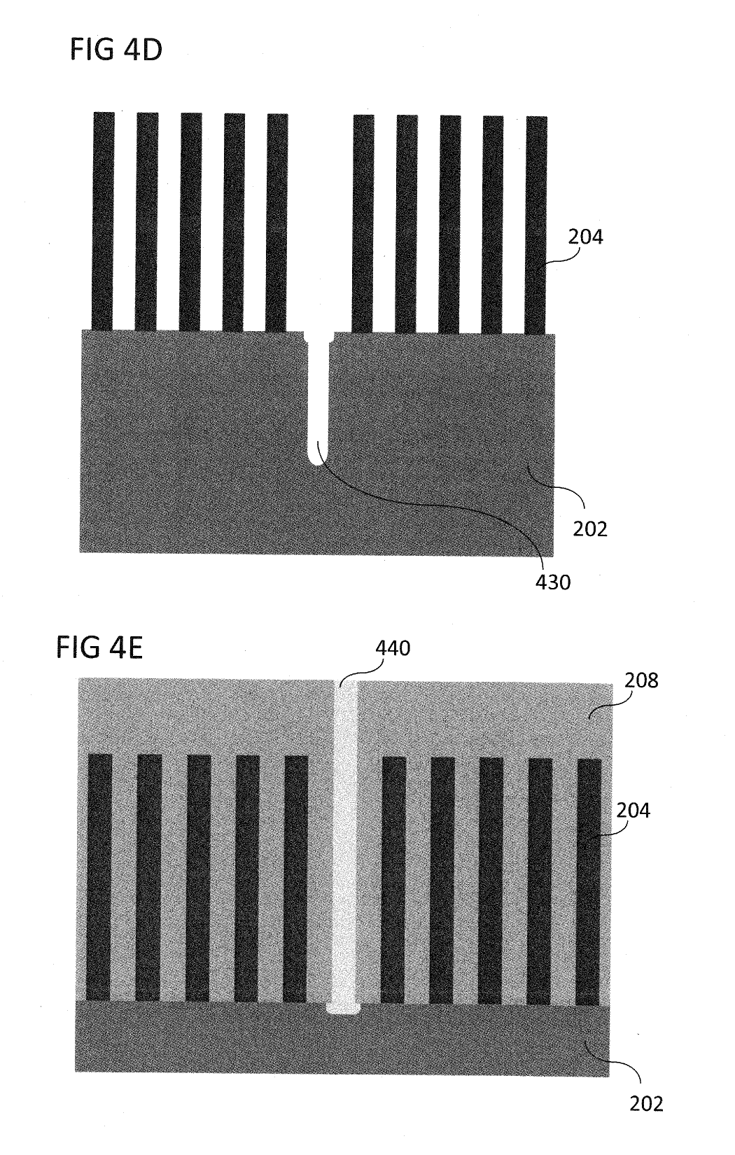

According to various embodiments, referring to method 100, the minimal feature size of the removal mask may be achieved by removing exclusively one structure element, which therefore also defines the minimal width of a recess or electrical contact which may be formed in the further processes. As exemplarily shown in FIG. 4A, removing part of the masking material 208 may include completely exposing the surface of exactly one structure element 404 which should be removed. Referring to this, removing part of the masking material to expose solely a part of the surface or part of the surface and a side of the one structure element 404 may be included as well. According to various embodiments, the further processing of the exposed exactly one structure element 404 as shown in FIG. 4A to FIG. 4E may be accomplished as already described in FIG. 1 and accordingly exemplified in FIG. 2D to FIG. 2H. According to various embodiments, the further processing may include removing the exposed exactly one structure element 404 and thereby forming a hollow space 418 as illustrated in FIG. 4B (cf. FIG. 2E), forming a recess 430 in the carrier 202 using the remaining masking material 208 as a removal mask as illustrated in FIG. 4C (cf. FIG. 2F), removing the remaining masking material 208 exposing all structure elements 204 after the recess 430 is formed as illustrated in FIG. 4D (cf. FIG. 2G). According to various embodiments, the further processing may also include forming material into a region between the remaining masking material 208 where the exactly one structure element 404 has been removed, which may include depositing material 440 into the hollow space 418 as illustrated in FIG. 4E (cf. FIG. 2H).

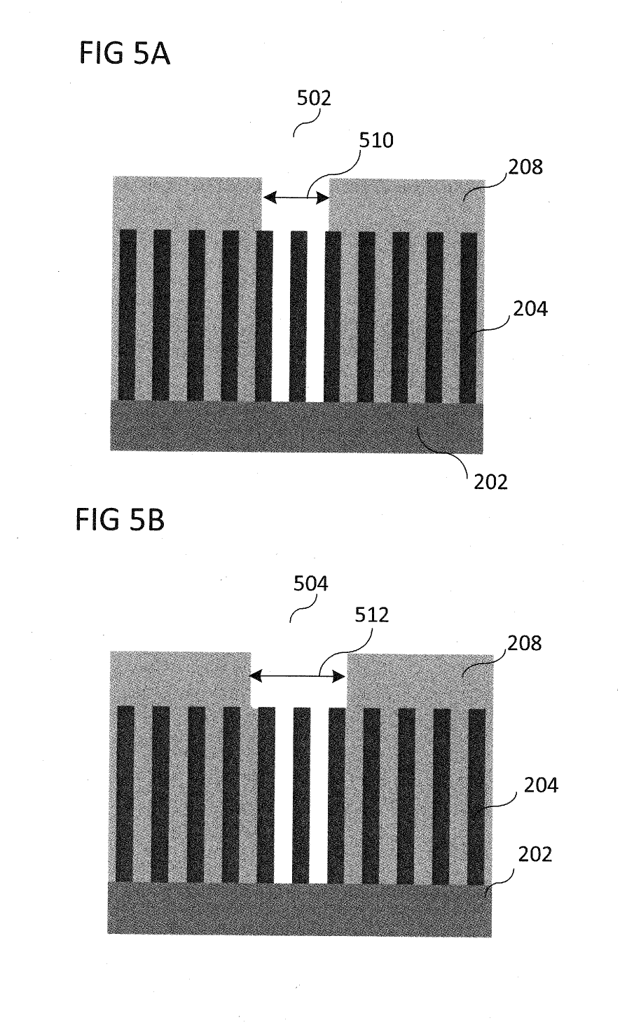

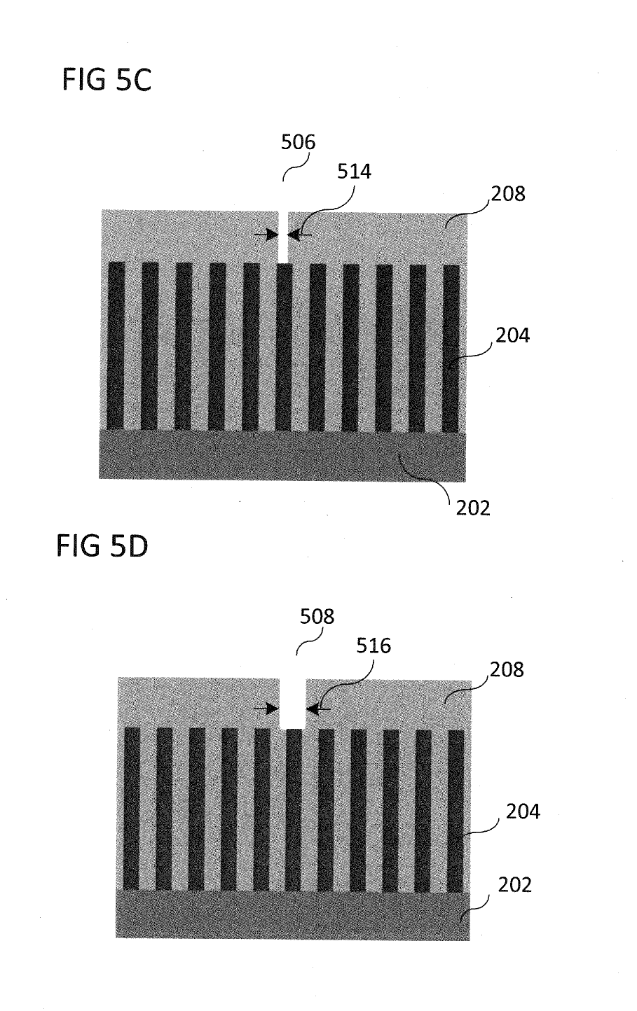

Referring to method 100, in various embodiments, partially removing masking material exposing at least one structure element may include a first removal process exposing the at least one structure element 404 forming a first removal structure in the masking material 208 having a first width, and a second removal process to widen the first removal structure forming a second removal structure having a second width which is greater than the first width. The first removal process and the second removal process can be applied in analogy to the already described method 100, as shown in FIG. 1 and exemplified in FIG. 2A to FIG. 2H, FIG. 3A and FIG. 3B. Accordingly, the first removal process may include at least one first etch process, e.g. anisotropic etch process as for example dry etching, and the second removal process may include at least one second etch process, e.g. an isotropic etch process as for example wet etching. Accordingly, FIG. 5A and FIG. 5B respectively show a cross section of a carrier 202 during an extended third processing stage, wherein part of the masking material 208 is removed exposing at least one structure element including a first removal structure 502 and second removal structure 504 in accordance with various embodiments. In analogy, FIG. 5C and FIG. 5D schematically show a cross section of a carrier 202 during an extended third processing stage respectively, wherein part of the masking material 208 is removed exposing exactly one structure element including a first removal structure 506 and second removal structure 508 in accordance with various embodiments. Thereby the first removal structure 502, 506 has a respective first width 510, 514 and a second removal structure 504, 508 has a respective second width 512, 516, which is greater than the first width 510, 514.

Widening the first removal structure 502, 506 using for example an isotropic second etch process may solve problems occurring due to overlay errors, since the first width 510, 514 of the first removal structure 502, 506 is smaller than the second width 512, 516 of the second removal structure 504, 508 so that overlay errors which indeed affect the first removal process may be compensated due to the widening of the first removal structure 502, 506 during the second removal process. In doing so, overlay errors smaller than half of the distance between two adjacent structure elements 204 may be compensated effectively, since the formation of the removal structure 502, 504, 506, 508 is assisted by the structure elements 204 of the periodic structure. It should be mentioned, that even if overlay errors affect the first removal process, as described before, the remaining masking material 208 finally forms a removal mask, which may be symmetrically aligned within the initial periodic structure 206 formed by the structure elements 204. It should be mentioned as well, that exposing all structure elements 204 during the process of exposing at least one structure element 204 will be counterproductive regarding the scope of the presented method.

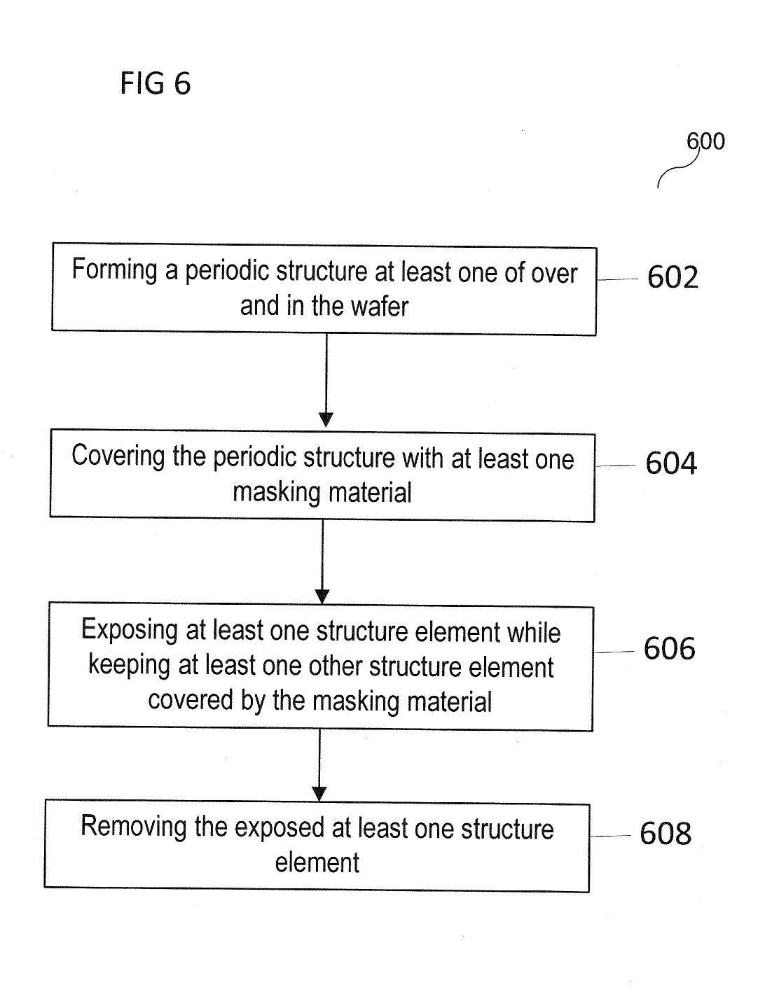

FIG. 6 shows a method for processing a wafer including a plurality of dies in accordance with various embodiments. The method 600 may include, in process 602, forming a periodic structure at least one of over and in the wafer, the periodic structure may include a plurality of structure elements arranged in a periodic structure along a main processing surface of the wafer, and, in process 604, covering the periodic structure with at least one masking material. The method may further include, in process 606, exposing at least one structure element while keeping at least one other structure element covered by the masking material, and, in process 608, removing the exposed at least one structure element. According to various embodiments, the remaining masking material may be used for further processes, e.g. forming at least one isolating trench or forming at least one electrical contact. As a result, arrays may be formed having structure elements being equal in shape and size and therefore having uniform electrical properties, even at the edges of the formed arrays.

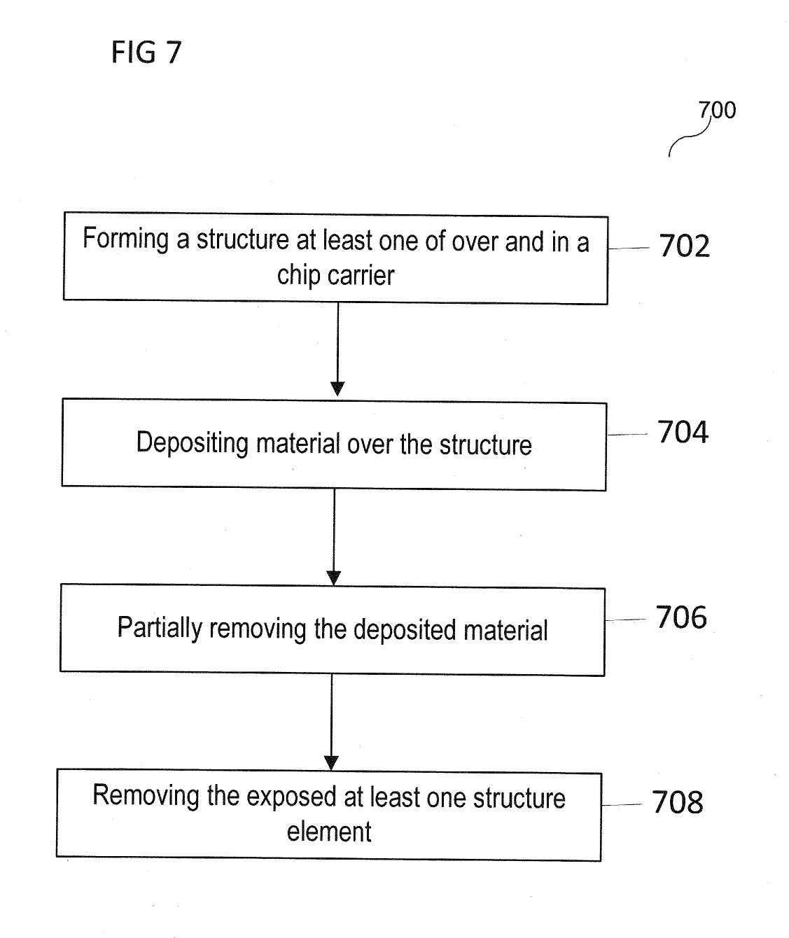

FIG. 7 shows a method for manufacturing a chip in accordance with various embodiments. The method 700 may include, in process 702, forming a structure at least one of over and in a chip carrier, the structure comprising a plurality of structure elements being arranged along the surface of the chip carrier in a periodic pattern, and, in process 704, depositing material over the structure to completely cover the plurality of structure elements. The method may further include, in process 706, partially removing the deposited material to expose at least one structure element but not all of the structure elements, and, in process 708, removing the exposed at least one structure element. According to various embodiments, the remaining masking material may be used for further processes e.g. forming at least one isolating trench or forming at least one electrical contact. As a result, arrays may be formed having structure elements being equal in shape and size and therefore having uniform electrical properties, even at the edges of the formed arrays (cf. FIG. 8).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method for processing a die, the method comprising:
forming a periodic structure at least one of over or in a carrier, the periodic structure comprising a plurality of structure elements, wherein each of the structure elements comprises a same width;
depositing masking material over one or more sidewalls and a top surface of the plurality of structure elements of the periodic structure;
partially removing the masking material to expose at least one of the structure elements but not all of the structure elements; and
removing the at least one exposed structure element.

2. The method of claim 1,
wherein the periodic structure is formed with a distance between two adjacent structure elements in the range from about 10 nm to about 10 μm.

3. The method of claim 1,
wherein the plurality of structure elements comprises at least one of a plurality of fins, cuboids, or balls formed over the carrier.

4. The method of claim 1,
wherein the plurality of structure elements comprises a plurality of holes formed into the carrier.

5. The method of claim 1,
wherein the masking material comprises a hard mask material, carbon or an organic masking material.

6. The method of claim 1,
wherein the at least one exposed structure element is removed by means of an etch process.

7. The method of claim 6,
wherein the etch process to remove the at least one exposed structure element comprises an isotropic etch process.

8. The method of claim 1, further comprising:
forming a recess in the carrier using the remaining masking material as a removal mask.

9. The method of claim 8,
wherein the recess in the carrier is formed by means of an etch process using the remaining masking material as an etch mask.

10. The method of claim 1, further comprising:
depositing a material into the region between the remaining masking material in which the at least one structure element has been removed.

11. The method of claim 10,
wherein the deposited material comprises an electrically conductive material.

12. The method of claim 1, further comprising:
after the removing of the at least one exposed structure element,
removing the rest of the masking material to expose the other structure elements.

13. The method of claim 1,
wherein the partially removing the masking material to expose at least one structure element comprises:
a first removal process to expose the at least one structure element to form a first removal structure in the masking material having a first width;
a second removal process to widen the first removal structure to form a second removal structure having a second width which is greater than the first width.

14. The method of claim 13,
wherein the first removal process comprises an anisotropic etch process.

15. The method of claim 13,
wherein the second removal process comprises an isotropic etch process.

16. A method for processing a wafer comprising a plurality of dies, the method comprising:
forming a periodic structure at least one of over and in the wafer, the periodic structure comprising a plurality of structure elements arranged in a periodic structure along a main processing surface of the wafer, wherein each of the structure elements comprises a same width;
covering one or more sidewalls and a top surface of the plurality of structure elements of the periodic structure with at least one masking material;
exposing at least one structure element while keeping at least one other structure element covered by the masking material; and
removing the exposed at least one structure element.

17. The method of claim 16,
wherein the periodic structure is formed with a distance between two adjacent structure elements in the range from about 10 nm to about 10 μm.

18. The method of claim 16,
wherein the plurality of structure elements comprises a plurality of fins, cuboids, or balls formed over the wafer.

19. The method of claim 16,
wherein the plurality of structure elements comprises a plurality of holes formed into the wafer.

20. The method of claim 16, further comprising:
forming a recess in the wafer using the remaining masking material as a removal mask.

21. The method of claim 20,
wherein the recess in the wafer is formed by means of an etch process using the remaining masking material as an etch mask.

22. The method of claim 16, further comprising:
depositing a material into the region between the remaining masking material in which the at least one structure element has been removed.

23. The method of claim 16,
wherein the exposing of the at least one structure element comprises:
a first removal process to expose the at least one structure element to form a first removal structure in the masking material having a first width;
a second removal process to widen the first removal structure to form a second removal structure having a second width which is greater than the first width.

24. The method of claim 23,
wherein the first removal process comprises an anisotropic etch process; and
wherein the second removal process comprises an isotropic etch process.

25. A method for manufacturing a chip, the method comprising:
forming a structure at least one of over and in a chip carrier, the structure comprising a plurality of structure elements being arranged along the surface of the chip carrier in a periodic pattern, wherein each of the structure elements comprises a same width;
depositing a material over the structure to completely cover one or more sidewalls and a top surface of the plurality of structure elements;
partially removing the deposited material to expose at least one structure element but not all of the structure elements; and
removing the at least one exposed structure element.
